(19) United States
(12) Patent Application Publication
(10) Pub. No.: US 2005/0048375 A1
(43) Pub. Date: Mar. 3, 2005

(54) Method of making an attenuated phase-shifting mask from a mask blank

(76) Inventor: Cheng-Ming Lin, Yun-Lin Hsien (TW)

Correspondence Address: SLATER & MATSIL, L.L.P., 17950 PRESTON ROAD, SUITE 1000, DALLAS, TX, 75252, US

(21) Appl. No.: 10/649,310

(22) Filed: Aug. 27, 2003

(51) Int. Cl. G03F 9/00; G03C 5/00

(52) U.S. Cl. 430/5; 430/322; 430/323; 430/324

(57) ABSTRACT

A method of patterning an attenuated phase-shifting mask from a mask blank, is provided. The mask blank has an attenuating and phase-shifting layer formed over a transparent layer. The phase-shifting layer has an initial thickness. The initial thickness of the phase-shifting layer is adapted to provide a first predetermined phase shift for a first wavelength of light passing therethrough. The initial thickness of the phase shifting layer is reduced to a first thickness. Portions of the phase-shifting layer are removed to form a pattern of clear areas. The first thickness of the phase-shifting layer at dark areas is adapted to provide a second predetermined phase shift for a second wavelength of light passing therethrough relative to the same light of the second wavelength passing through the clear areas. The first wavelength differs from the second wavelength.

### TECHNICAL FIELD

The present invention generally relates to masks used for photolithography in semiconductor device fabrication, and more particularly to attenuated phase-shifting masks.

### BACKGROUND

Lithography is one of the key technologies to the progression of semiconductor fabrication. In a typical lithographic process, a patterned mask is used to transfer an image of the mask's pattern onto a photoresist layer. In the early stages of lithography, masks would completely block projected light from passing through dark areas and allow the light to pass through the clear areas, which worked fine until circuit features began to shrink to much smaller geometries. As the desired patterns exposed on the photoresist became smaller and as the wavelength of light projected through masks became smaller, the complexity and features of masks changed accordingly. One example of a more recently developed mask technology is attenuated phase-shifting masks.

To form a conventional attenuated phase-shifting mask, a mask blank is often used as a starting point. A conventional mask blank 20, as shown in FIG. 1 for example, has a transparent layer 22 with an attenuating and phase-shifting layer 24 formed on it. The phase-shifting layer 24 may have multiple layers of different materials, or it may be a single layer of one material, for example. A pattern is formed in the phase-shifting layer 24 by removing portions of the phase-shifting layer 24 at the clear areas 26, as shown in FIG. 2. The remaining portions of the phase-shifting layer 24 act as the dark areas 28. In a conventional attenuated phase-shifting mask 30 (see e.g., FIG. 2), the light passing through the clear areas 26 may be substantially unchanged, as it only passes through the transparent layer 22. The transparent layer 22 is often made from clear quartz or glass, for example. At the dark areas 28, a small fraction of the light (e.g., 2-20%) is permitted to pass through the attenuating and phase-shifting layer 24. Hence, the light passing through the phase-shifting layer 24 is significantly attenuated (but not completely blocked). Also, as the light passes through the dark areas 28 of the mask 30, the phase-shifting layer 24 causes the light exiting the mask 30 at the dark areas 28 (see e.g., line-A in FIG. 2) to have a shifted phase relative to the same light exiting the mask 30 at the clear areas 26 (see e.g., line-B in FIG. 2). In most cases, it is desirable to have the light passing through the dark areas 28 shifted by about 180 degrees to provide destructive interference with light passing through the clear areas 26 for certain regions of the image pattern. Also, some constructive interference may occur at other regions of the image pattern. The desired result is a larger contrast in light intensity between dark areas 28 and clear areas 26 for the image pattern projected onto the photoresist.

Many companies that fabricate semiconductor devices purchase mask blanks 20 for use in making their attenuated phase-shifting masks 30, rather than making the mask blanks 20 themselves. Such pre-fabricated mask blanks 20 are usually designed and made to provide a specified phase shift and transmittance for a specific wavelength of light. For example, a mask blank 20 designed for use with 193 nm light may have a certain material for the phase-shifting layer 24 (or certain materials for a multi-layer composite phase-shifting layer 24) and a certain thickness Dₒ for the phase-shifting layer 24 (see e.g., FIG. 1) to provide a desired phase-shift and transmittance through the dark areas 28 relative to the clear areas 26 (see e.g., FIG. 2). Often a desired phase-shift is equal to or greater than about 180 degrees and a desired transmittance through the dark areas is less than or equal to about 6%, for example.

However, because the makers of such mask blanks 20 often supply numerous companies, they are often relatively slow to change with the progression of one or two companies until there is demand from a majority of companies supplied. Often, it may be more profitable to implement new mask blanks only when the majority of companies are ready for them. Hence, if one company is ahead of or leads its competitors and is ready for the next generation mask blanks sooner, the mask blank supplier may not keep up. Or if the mask blank supplier does strive to keep up with a leading fabricator, this may be a disadvantage to the leading fabricator because the next generation mask blanks will then be readily available to all of its competitors. Thus, a need exists for a way to continue using a current generation of mask blanks provided by a mask blank supplier while still being able to push into the next generation of fabrication processes.

In the case where a mask blank supplier cannot affordably mass produce next generation mask blanks soon enough for a leading fabricator, which is ready for them, the slower pace of competing fabricators may slow the progression of the leading fabricator. This may be especially true if the leading fabricator is dependent upon the mask blank supplier for providing its mask blanks. For example, most of the industry may be using 193 nm light for lithography and a leading company may be ready to use 157 nm light to provide smaller geometries. In such case, the leading company will not want to wait for its competitors to catch up. Thus, it would be highly desirable for the leading fabricator to have the ability to use readily available mask blanks designed for the current generation processes in its next generation fabrication processes.

### SUMMARY OF THE INVENTION

The problems and needs outlined above are addressed by the present invention. In accordance with one aspect of the present invention, a method of patterning an attenuated phase-shifting mask is provided. In this method, a mask blank is provided. The mask blank has an attenuating and phase-shifting layer formed over a transparent layer. The phase-shifting layer has an initial thickness. The initial thickness of the phase-shifting layer is adapted to provide a first predetermined phase shift for a first wavelength of light passing therethrough. The initial thickness of the phase shifting layer is reduced to a first thickness. Portions of the phase-shifting layer are removed to form a pattern of clear areas. The first thickness of the phase-shifting layer at dark areas is adapted to provide a second predetermined phase shift for a second wavelength of light passing therethrough relative to the same light of the second wavelength passing through the clear areas. The first wavelength differs from the second wavelength.

The method may further include the removal of portions of the transparent layer to form a recess with a first recess depth at the clear areas. The portions of the transparent layer may be removed by reactive ion etching using an etch chemistry including SF6 and/or CF4, for example. Part of the phase-shifting layer with a second thickness may remain at the clear areas, wherein the second thickness is less than the first thickness. The second predetermined phase shift may be approximately equal to or greater than the first predetermined phase shift. Typically, the second wavelength will be greater than the first wavelength. The first predetermined phase shift may be about 180 degrees, and the second predetermined phase shift may be equal to or greater than about 180 degrees, for example. The initial thickness of the phase-shifting layer may be adapted to provide a first optical transmission for light of the first wavelength, and the first thickness of the phase-shifting layer at the dark areas may be adapted to provide a second optical transmission. The second optical transmission is preferably less than or equal to about 6%, for example. Yet, as another example, the second optical transmission may be between about 5% and about 15%. The initial thickness of the attenuation and phase-shifting layer may be reduced by reactive ion etching using an etch chemistry including at least one of SF6 and CF4, for example.

In accordance with another aspect of the present invention, method of making a patterned attenuated phase-shifting mask from a mask blank is provided. The mask blank includes an attenuation and phase-shifting layer with a first default thickness and a transparent layer with a second default thickness. The attenuation and phase-shifting layer covers the transparent layer. In this method, a circuit design pattern is formed. The formation of the circuit design pattern includes forming a plurality of clear areas and forming a plurality of dark areas. The formation of dark areas includes reducing a thickness of the attenuation and phase-shifting layer from the first default thickness to a first adjusted thickness. The formation of clear areas includes removing portions of the attenuation and phase-shifting layer at clear areas, and reducing a thickness of the transparent layer at the clear areas from the second default thickness to a second adjusted thickness.

The attenuated phase-shifting mask may be designed for light with a target wavelength. The first adjusted thickness and the second adjusted thickness may be designed so that the phase of light passing through dark areas differs from the phase of light passing through clear areas by a predetermined phase shift. The predetermined phase shift may be about 180 degrees, for example. The first thickness also, or in alternative, may be designed so that light passing through dark areas has a predetermined optical transmission. The predetermined optical transmission may be between about 5% and about 15%, for example. Also, the predetermined optical transmission may be between about 2% and about 20%. The thickness of the attenuation and phase-shifting layer may be reduced by etching (e.g., reactive ion etching), for example. Also, the portions of the attenuation and phase-shifting layer may be removed by etching. Furthermore, the thickness of the transparent layer may be reduced at the clear areas by etching.

### BRIEF DESCRIPTION OF THE DRAWINGS

The following is a brief description of the drawings, which show illustrative embodiments of the present invention and in which:

FIG. 1 is a side cross-section view for a portion of a conventional mask blank;

FIG. 2 is a side cross-section view for a portion of a conventional attenuate phase-shifting mask formed from the mask blank of FIG. 1;

FIGS. 3 and 4 illustrate a method of making an attenuated phase-shifting mask from the mask blank of FIG. 1 in accordance with a first embodiment of the present invention; and

FIGS. 5 and 6 illustrate a method of making an attenuated phase-shifting mask from the mask blank of FIG. 1 in accordance with a second embodiment of the present invention.

### DETAILED DESCRIPTION OF ILLUSTRATIVE EMBODIMENTS

Referring now to the drawings, wherein like reference numbers are used herein to designate like elements throughout the various views, illustrative embodiments of the present invention are shown and described. The figures are not necessarily drawn to scale, and in some instances the drawings have been exaggerated and/or simplified in places for illustrative purposes only. One of ordinary skill in the art will appreciate the many possible applications and variations of the present invention based on the following illustrative embodiments of the present invention.

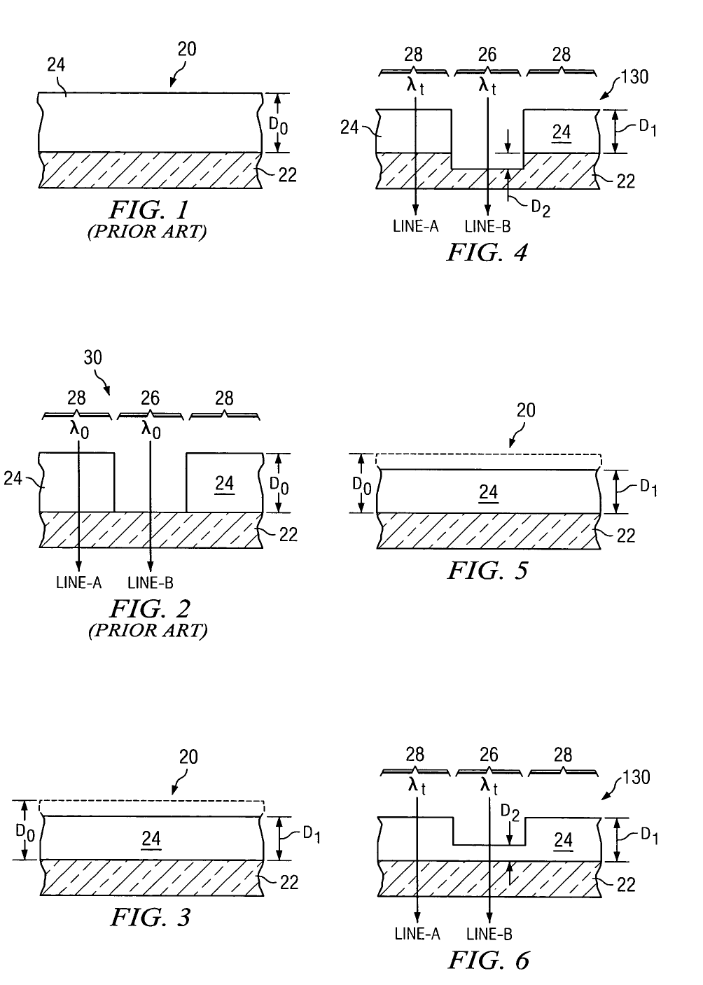

Generally, an embodiment of the present invention provides a structure and method of using a mask blank designed for one wavelength of light to make an attenuated phase-shifting mask for use with another wavelength of light. FIGS. 1-2 illustrate the use of a mask blank 20 for making a conventional attenuated phase-shifting mask 30. The conventional use of mask blanks 20 will be described in detail first (see FIGS. 1 and 2). Then, two illustrative embodiments of the present invention will be described in detail (see FIGS. 3-6).

FIG. 1 shows a side cross-section view for part of a conventional mask blank 20. The mask blank 20 may be pre-fabricated by a mask company and supplied to a fabricator for use in making an attenuated phase-shifting mask, for example. The mask blank 20 has an attenuating and phase-shifting layer 24 (referred to as the “attPS layer” hereafter) formed over a transparent layer 22. The transparent layer 22 is typically made from clear quartz or glass, for example. However, the transparent layer 22 may be made from other materials, as will be known to or realized by one of ordinary skill in the art.

The attPS layer 24 has an initial thickness (Dₒ), as shown in FIG. 1. To prepare the mask blank 20 for use, a pattern of clear areas 26 is formed by removing select portions of the attPS layer 24 (see FIG. 2). The portions of the attPS layer 24 may be removed using a variety of techniques, such as etching (wet or dry etching), for example. The mask blank 20 is designed for the attPS layer 24 to be removed down to the transparent layer 22, as shown in FIG. 2. The mask blank 20 is designed for use with a specific wavelength (λₒ) of light (or a specific range of wavelengths of light). For example, a mask blank 20 may be designed for use with light projected at a wavelength of about 193 nm. In such case, the mask 30 formed in FIG. 2 would most likely not work properly for use with light projected though the mask 30 at a wavelength of 157 nm, for example. This is because the thickness Dₒ of the attPS layer 24 is generally a function of the wavelength (λₒ) of the light source.

More specifically, the thickness Dₒ of the dark areas 28 (see FIG. 2) may be chosen to provide a specific phase shift with a preferred transmittance level. Referring to FIG. 2 for example, the attenuated phase-shifting mask 30 formed with a conventional process of using a mask blank 20 for its designed wavelength (λₒ) may provide a phase shift of about 180 degrees for light passing through the dark areas 28 (e.g., line-A in FIG. 2) relative to the same light passing through the clear areas 26 (e.g., line-B in FIG. 2). Also, the mask 30 of FIG. 2 may provide an optical transmission or transmittance of the light passing through the dark areas 26 (e.g., line-A) of about 6%, for example. The relevant mathematical formulas for calculating the phase shift and transmittance for the mask 30 shown in FIG. 2 are as follows:
Φₒ=(2(nₒ−1)Dₒ/λₒ)180 °
Tₒ=Aₒ exp(−4πDₒkₒ/λₒ)
where:
Φₒ=phase shift of light through line-A relative to light through line-B (see FIG. 2), based on using Dₒ and λₒ
nₒ=refractive index of attPS layer material at λₒ
Dₒ=attPS layer thickness on mask blank (as received from mask blank provider)
λₒ=wavelength of light for which the blank mask was designed
Tₒ=transmittance through line-A (see FIG. 2) based on using Dₒ and λₒ
Aₒ=constant for attPS layer material at λₒ
kₒ=extinction coefficient for attPS layer material at λₒ

Based on these equations provided above for phase shift (Φₒ) and transmittance (Tₒ), note that changing the wavelength (λ₀) for the light projected through the mask will affect the phase shift and transmittance. Thus, using a mask 30 made from a mask blank 20 designed for one wavelength of light (e.g., λₒ) using a conventional method (see e.g., FIGS. 1-2) for another wavelength of light may provide an undesirable phase shift and/or an undesirable transmittance. For example, if the desired phase shift is about 180 degrees and the desired transmittance is about 6%, and the mask blank 20 is designed to provide such values for a light wavelength of 193 nm passing through the mask of FIG. 2, then projecting light with a wavelength of 157 nm will not provide the same phase shift and transmittance as provided by the 193 nm light.

FIGS. 3 and 4 illustrate a method of forming a first embodiment of the present invention. The first embodiment provides a way to utilize a mask blank 20 designed for a first wavelength (λₒ) of light to provide a desired phase shift and transmittance for a second wavelength (λₜ) of light. The wavelength of light used with attenuated phase-shifting masks in semiconductor fabrication generally tends to decrease as technology progresses to enable the patterning of smaller circuit geometries. Hence, the embodiments described herein are discussed in the context of decreasing the wavelength of light. However, embodiments of the present invention may be useful when the wavelength of light is increased as well.

Referring again to FIG. 1, a process of forming the first embodiment may begin with a conventional mask blank 20 having an attPS layer 24 with an initial thickness Dₒ, which is designed for use with a first wavelength (λₒ) of light. As shown in FIG. 3, the initial thickness Dₒ of the attPS layer 24 is reduced to a first thickness D₁. The thickness of the attPS layer 24 may be reduced using a variety of techniques, including (but not necessarily limited to) etching, chemical mechanical polishing (CMP), or any combination thereof, for example. Wet etching, reactive ion etching (RIE), ion milling, or any combination thereof, are among the methods of etching that may be used. A preferred process of reducing the thickness of the attPS layer 24 (see FIG. 3) is using a RIE process. Also, various etch chemistries may be used. Preferably, the etch chemistry used to etch the attPS layer 24 is somewhat selective against etching the transparent layer 22; however, etch selectivity is not necessary. SF₆ and/or CF₄ may be used in the etch chemistry of a RIE process, for example. One of ordinary skill in the art will realize many other processes and/or chemistries that may be used to reduce the thickness of the attPS layer 24 from Dₒ to D₁.

Next, as shown in FIG. 4, select portions of the attPS layer 24 are removed to form a pattern for the clear areas 26 of the mask 130. Also, portions of the transparent layer 22 are removed at the clear areas 26 (see FIG. 4) to a depth D₂. In other words, the thickness of the transparent layer 22 at the clear areas 26 is reduced, and a recess with a depth D₂ is formed at the clear areas 26. Removing portions of the attPS layer 24 and the transparent layer 22 at the clear areas 26 may or may not be performed during or with the same process (e.g., etching). Preferably, the removal of attPS and transparent layer materials at the clear areas 26 is performed using a RIE process with an etch chemistry of SF₆ and/or CF₄, for example. However, one of ordinary skill in the art should realize other processes that may be used for such removal step(s). The following equations may be used to calculate the values of D₁ and D₂ to provide desired values of phase shift and transmittance for a given wavelength (λₜ) of light:
Φₜ=[2(nₜ−1)D₁/λₜ]180°+[2(n_{c}−1)D₂/λₜ]180 °
Tₜ=Aₜ exp(−4πD₁kₜ/λₜ)
D₁=−λₜ1n[Tₒ/Aₜ]/4πkₜ
D₂=λₜ[1−2(nₜ−1)D₁/λₜ]/[2(n_{c-1})]
where:
Φₜ=phase shift of light through line-A relative to light through line-B, based on using D₁ for dark area, D₂ for clear area, and λₜ, where λₜ<λₒ
nₜ=refractive index of attPS layer material (dark area) at )q
n_{c}=refractive index of transparent layer material (clear area) at ?q
D₁=reduced attPS layer thickness on mask blank at dark area
D₂=depth of recess at clear area
λₜ=wavelength of light used
Tₜ=transmittance through line-A based on using D₁, D₂, and λₜ
Aₜ=constant for attPS layer material at λₜ
kₜ=extinction coefficient for attPS layer material at λₜ

Thus, the values of D₁ and D₂ (see FIG. 4) may be adjusted and tuned to provide optimum values for phase shift and transmittance through the dark areas 28 (line-A in FIG. 4) relative to the clear areas 26 (line-B in FIG. 4). For example, if the mask blank 20 is designed to provide a phase shift of about 180 degrees with a dark area transmittance of about 6% at λₒ, it may be possible to obtain a phase shift of about 180 degrees or more and a dark area transmittance of about 6% or less using λₜ and the same mask blank via the method and structure of the first embodiment (e.g., as shown in FIGS. 3 and 4). However, other transmittance values or ranges (e.g., between 2% and 20%) may be desirable for certain applications.

FIGS. 5 and 6 illustrate a method of forming a second embodiment of the present invention. The second embodiment provides another way to utilize a mask blank 20 designed for a first wavelength (λₒ) of light to provide a desired phase shift and transmittance for a second wavelength (λₜ) of light.

Referring again to FIG. 1, a process of forming the second embodiment may begin with a conventional mask blank 20 having an attPS layer 24 with an initial thickness Dₒ, which is designed for use with a first wavelength (λₒ) of light. As shown in FIG. 5, the initial thickness Dₒ of the attPS layer 24 is reduced to a first thickness D₁. The thickness of the attPS layer 24 may be reduced using a variety of techniques, including (but not necessarily limited to) etching, chemical mechanical polishing (CMP), or any combination thereof, for example. Wet etching, reactive ion etching (RIE), ion milling, or any combination thereof, are among the methods of etching that may be used, for example. A preferred process of reducing the thickness of the attPS layer 24 (see FIG. 5) is using a RIE process. Also, various etch chemistries may be used. Preferably, the etch chemistry used to etch the attPS layer 24 is somewhat selective against etching the transparent layer 22; however, etch selectivity is not necessary. SF₆ and/or CF₄ may be used in a RIE process, for example. One of ordinary skill in the art will likely realize many other processes and/or chemistries that may be used to reduce the thickness of the attPS layer 24 from Dₒ to D₁.

Next, as shown in FIG. 6, portions of the attPS layer 24 are removed in a pattern to form the clear areas 26. In the second embodiment, part of the attPS layer 24 having a thickness D₂ remains over the transparent layer 22 at the clear areas 26 (see FIG. 6). Preferably, the removal of attPS layer material at the clear areas 26 is performed using a RIE process with an etch chemistry of SF₆ and/or CF₄, for example. However, one of ordinary skill in the art should realize other processes that may be use for such removal, including (but not necessarily limited to) wet etching, RIE, ion milling, or any combination thereof, for example. The following equations may be used to calculate the phase shift and transmittance, and/or to determine the values of D₁ and D₂ that provide desired values of phase shift and transmittance, for a given wavelength (λₜ) of light:
Φₜ=[2(nₜ−1)(D₁−D₂)/λₜ]180°
T₁=L₁/Lₒ=Aₜ exp(−4πkₜD₁/λₜ)
T₂=L₂/Lₒ=Aₜ exp(−4πkₜD₂/λₜ)
Tₜ=L₁/L₂=T₁/T₂=exp[−4πkₜ(D₁−D₂)/λₜ]
where:
Φₜ=phase shift of light through line-A relative to light through line-B, based on using D₁ for dark area, D₂ for clear area, and λₜ, where λₜ<λₒ
nₜ=refractive index of attPS layer material at λₜ
D₁=attPS layer thickness on mask blank at dark area
D₂=attPS layer thickness on mask blank at clear area
λₜ=wavelength of light used
Tₜ=transmittance through line-A relative to light through line-B based on using D₁, D₂, and λₜ
T₁=transmittance through line-A based on using D₁ and λₜ
T₂=transmittance through line-B based on using D₂ and λₜ
Aₜ=constant for attPS layer material at λₜ
kₜ=extinction coefficient for attPS layer material at λₜ

Thus, the values of D₁ and D₂ (see FIG. 6) may be adjusted and tuned to provide optimum values for phase shift and transmittance through the dark areas 28 (line-A in FIG. 6) relative to the clear areas 26 (line-B in FIG. 6). For example, if the mask blank 20 is designed to provide a phase shift of about 180 degrees with a dark area transmittance of about 6% at λₒ, it may be possible to obtain a phase shift of about 180 degrees or more and a dark area transmittance of about 6% or less using λₜ and the same mask blank via the method and structure of the second embodiment (e.g., as shown in FIGS. 5 and 6). Also, if the first embodiment does not allow for a desired combination of phase shift and transmittance, then the second embodiment may be better suited to do so for a given wavelength (λₜ) and mask blank combination (and vice versa).

The precise depth of an etch in any of the etch processes mentioned above herein may be controlled by a variety of techniques, including but not limited to: a timed process, selective etching chemistry, an endpoint signal control, or any combination thereof, for example. For any of the embodiments of the present invention, the attPS layer may be made from a variety of materials, including but not limited to: MoSiON, AlSiO, ZrSiO, TiSiN, TiSiON, TaSiN, TaSiO, or any combination thereof, for example. Although the embodiments above have been described in the context of using a conventional pre-fabricated mask blank 20 (see e.g., FIG. 1) as a starting point, an embodiment of the present invention may be used with other types and/or other configurations of mask blanks (not shown) as well.

Embodiments of the present invention may provide numerous advantages, such as:
Ability to use current generation mask blanks for next generation processes to gain an advantage over the competition that is still using current generation processes;
Less dependence on the progress of mask blank makers/suppliers for the progress of a fabricator;
Ability to use an inventory of past generation mask blanks for next generation processing needs;
Ability to tune and adjust the phase shift and/or transmittance of an attenuated phase-shifting mask built from a pre-fabricated mask blank;
Flexibility in the use of different wavelengths of light; and/or
Ability to test and quickly implement different wavelengths of light using existing pre-fabricated mask blanks.

It will be appreciated by those skilled in the art having the benefit of this disclosure that embodiments the present invention provide methods of forming an attenuated phase-shifting mask for use with one wavelength of light from a mask blank designed for use with another wavelength of light. It should be understood that the drawings and detailed description herein are to be regarded in an illustrative rather than a restrictive manner, and are not intended to limit the invention to the particular forms and examples disclosed. On the contrary, the invention includes any further modifications, changes, rearrangements, substitutions, alternatives, design choices, and embodiments apparent to those of ordinary skill in the art, without departing from the spirit and scope of this invention, as defined by the following claims. Thus, it is intended that the following claims be interpreted to embrace all such further modifications, changes, rearrangements, substitutions, alternatives, design choices, and embodiments.

1. A method of patterning an attenuated phase-shifting mask, comprising:
providing a mask blank, wherein the mask blank has an attenuating and phase-shifting layer formed over a transparent layer, the phase-shifting layer having an initial thickness, wherein the initial thickness of the phase-shifting layer is adapted to provide a first predetermined phase shift for a first wavelength of light passing therethrough;
reducing the initial thickness of the phase shifting layer to a first thickness; and
removing portions of the phase-shifting layer to form a pattern of clear areas, wherein the first thickness of the phase-shifting layer at dark areas is adapted to provide a second predetermined phase shift for a second wavelength of light passing therethrough relative to the same light of the second wavelength passing through the clear areas, wherein the first wavelength differs from the second wavelength.

2. The method of claim 1, further comprising:
removing portions of the transparent layer to form a recess with a first recess depth at the clear areas.

3. The method of claim 2, wherein the portions of the transparent layer are removed by reactive ion etching using an etch chemistry including at least one of SF₆ and CF₄.

4. The method of claim 1, wherein part of the phase-shifting layer with a second thickness remains at the clear areas, wherein the second thickness is less than the first thickness.

5. The method of claim 1, wherein the second predetermined phase shift is approximately equal to or greater than the first predetermined phase shift.

6. The method of claim 5, wherein the second wavelength is greater than the first wavelength.

7. The method of claim 1, wherein the first predetermined phase shift is about 180 degrees.

8. The method of claim 1, wherein the second predetermined phase shift is equal to or greater than about 180 degrees.

9. The method of claim 1, wherein the initial thickness of the phase-shifting layer is adapted to provide a first optical transmission for light of the first wavelength, and wherein the first thickness of the phase-shifting layer at the dark areas is adapted to provide a second optical transmission.

10. The method of claim 9, wherein the second optical transmission is less than or equal to about 6%.

11. The method of claim 1, wherein the transparent layer comprises a quartz material.

12. The method of claim 1, wherein the initial thickness of the attenuation and phase-shifting layer is reduced by reactive ion etching using an etch chemistry including at least one of SF₆ and CF₄.

13. A method of making a patterned attenuated phase-shifting mask from a mask blank, the mask blank including an attenuation and phase-shifting layer with a first default thickness and a transparent layer with a second default thickness, the attenuation and phase-shifting layer covering the transparent layer, the method comprising:
forming a circuit design pattern that includes forming a plurality of clear areas and forming a plurality of dark areas;
wherein the forming dark areas includes reducing a thickness of the attenuation and phase-shifting layer from the first default thickness to a first adjusted thickness; and
wherein forming clear areas includes:
removing portions of the attenuation and phase-shifting layer at clear areas, and
reducing a thickness of the transparent layer at the clear areas from the second default thickness to a second adjusted thickness.

14. The method of claim 13, wherein the transparent layer comprises a quartz material.

15. The method of claim 13, wherein the attenuated phase-shifting mask is designed for light with a target wavelength, and wherein the first adjusted thickness and the second adjusted thickness are designed so that the phase of light passing through dark areas differs from the phase of light passing through clear areas by a predetermined phase shift.

16. The method of claim 15, wherein the predetermined phase shift is about 180 degrees.

17. The method of claim 13, wherein the attenuated phase-shifting mask is designed for light with a target wavelength, and wherein the first thickness is designed so that light passing through dark areas has a predetermined optical transmission.

18. The method of claim 17, wherein the predetermined optical transmission is between about 5% and about 15%.

19. The method of claim 17, wherein the predetermined optical transmission is between about 2% and about 20%.

20. The method of claim 13, wherein the thickness of the attenuation and phase-shifting layer is reduced by etching.

21. The method of claim 20, wherein the etching of the attenuation and phase-shifting layer includes reactive ion etching.

22. The method of claim 21, wherein the reactive ion etching uses an etching chemical selected from a group consisting of SF₆ and CF₄.

23. The method of claim 13, wherein the portions of the attenuation and phase-shifting layer are removed by etching.

24. The method of claim 23, wherein the etching of the attenuation and phase-shifting layer includes reactive ion etching.

25. The method of claim 24, wherein the reactive ion etching uses an etching chemical selected from a group consisting of SF₆ and CF₄.

26. The method of claim 13, wherein the thickness of the transparent layer is reduced at the clear areas by etching.

27. The method of claim 26, wherein the etching of the transparent layer includes reactive ion etching.

28. The method of claim 27, wherein the reactive ion etching uses an etching chemical selected from a group consisting of SF₆ and CF₄.

29. An attenuated phase-shifting mask comprising:
a transparent layer;
an attenuating and phase-shifting layer over the transparent layer;
dark areas having the phase-shifting layer at a first thickness; and
clear areas having the phase-shifting layer removed therefrom and having a recess of a recess depth formed in the transparent layer, wherein the first thickness at the dark areas and the first recess depth at the clear areas are chosen such that a certain phase-shift and transmittance is provided for light through the dark areas relative to the clear areas.

30. The attenuated phase-shifting mask of claim 29, wherein the transparent layer comprises quartz.

31. The attenuated phase-shifting mask of claim 29, wherein the attenuated phase-shifting mask is made from an attenuated phase-shifting mask blank having an attenuation and phase-shifting layer with an initial thickness greater than the first thickness at the dark areas.

32. The attenuated phase-shifting mask of claim 31, wherein the mask blank is designed for light with a first wavelength, but the attenuated phase-shifting mask formed therefrom is designed for light with a second wavelength, wherein the second wavelength differs from the first wavelength.

33. The attenuated phase-shifting mask of claim 32, wherein the second wavelength is smaller than the first wavelength.

34. The attenuated phase-shifting mask of claim 29, wherein the certain phase-shift is equal to or greater than about 180 degrees, and wherein the certain transmittance is less than or equal to about 6%.

35. An attenuated phase-shifting mask comprising:
a transparent layer;
an attenuating and phase-shifting layer over the transparent layer;
dark areas having the phase-shifting layer at a first thickness; and
clear areas having the phase-shifting layer at a second thickness, wherein the first thickness at the dark areas is greater than the second thickness at the clear areas, and wherein the first thickness and second thickness are chosen such that a certain phase-shift and transmittance is provided for light through the dark areas relative to the clear areas.

36. The attenuated phase-shifting mask of claim 35, wherein the attenuated phase-shifting mask is made from an attenuated phase-shifting mask blank having an attenuating and phase-shifting layer with an initial thickness greater than the first thickness at the dark areas.

37. The attenuated phase-shifting mask of claim 36, wherein the mask blank is designed for light with a first wavelength, but the attenuated phase-shifting mask formed therefrom is designed for light with a second wavelength, wherein the second wavelength differs from the first wavelength.

38. The attenuated phase-shifting mask of claim 37, wherein the second wavelength is smaller than the first wavelength.

39. The attenuated phase-shifting mask of claim 35, wherein the certain phase-shift is equal to or greater than about 180 degrees, and wherein the certain transmittance is less than or equal to about 6%.
